(19) United States
(12) Patent Application Publication
(10) Pub. No.: US 2010/0001723 A1
(43) Pub. Date: Jan. 7, 2010

(54) BRIDGE TYPE SENSOR WITH TUNABLE CHARACTERISTIC

(75) Inventors: Hans Van Zon, Eindhoven (NL); Jaap Ruigrok, Eindhoven (NL); Frederik Willem Maurits Vanhelmont, Eindhoven (NL); Gunnar Schulz-Mewes, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 11/721,681

(22) PCT Filed: Dec. 15, 2005
(86) PCT No.: PCT/IB05/54270

§ 371 Date: Sep. 22, 2009

(30) Foreign Application Priority Data
Dec. 28, 2004 (EP) 04107010.3

(51) Int. Cl. G01R 33/02

(52) U.S. Cl. 324/252

(57) ABSTRACT

A bridge type magnetic sensor is disclosed having four resistive elements in a bridge arrangement, two of the resistive elements on opposing sides of the bridge having a magnetoresistive characteristic such that their resistance increases with increasing positive magnetic field and with increasing negative magnetic field. A frequency doubling is obtained because the output characteristic of the magnetic sensor is a V-shaped curve, where the signal rises for increasing positive and negative fields.

This invention relates to magnetic sensors using four magnetoresistive elements coupled in a bridge arrangement as well as methods of using and manufacturing the same.

It is known from WO 02/097464 that magnetic sensors are used, inter alia, for reading data in a head for a hard disk or tape, or in the automobile industry for measuring angles and rotational speeds and to determine the position. Magnetic sensors have the advantage that they are comparatively insensitive to dust and enable measuring to take place in a contact-free manner. Sensors used for automotive applications can be resistant to high temperatures of approximately 200° C.

In the known sensor, the resistance of the magnetic elements depends on the size and orientation of the magnetic field due to a magnetoresistance effect. The magnetic elements are arranged in a Wheatstone bridge configuration. By virtue of said Wheatstone bridge configuration, the sensor is less sensitive to temperature than in the case of a single magnetoresistance element. The magnetic elements are Giant Magneto resistive (GMR) devices which comprise a pinned layer with a fixed orientation of the axis of magnetization and a layer with a free orientation of the axis of magnetization, which adopts the orientation of the magnetic field to be measured. The magnetoresistance value is determined, inter alia, by the angle between the axis of magnetization of the pinned layer and the freely rotatable axis of magnetization. In the Wheatstone bridge the axes of magnetization of the pinned layers in the bridge portions are oppositely directed. The difference in resistance and therefore output voltage between the two bridge portions is converted to a differential amplitude voltage signal which is a measure of the angle and the strength of the magnetic field. To address sensitivity to offset voltage and drift in offset voltage, compensating resistors with an opposing temperature coefficient are coupled in parallel with the sensors.

Another example shown in U.S. Pat. No. 6,501,271 has Giant Magneto resistive (GMR) sensors arranged in Wheatstone bridge configurations to enable compensation for temperature changes.

Another example known from US patent application 2002/0006017 shows a GMR Wheatstone bridge used for angular sensing and having correction elements coupled in series to reduce the non-linearity. The correction elements are magnetic sensors placed at a different angle to that of the main sensing element, or having a pinned layer with a bias magnetization at a different angle.

WO 99/08263 explains that Giant magnetoresistance is present in heterogeneous magnetic systems with two or more ferromagnetic components and at least one nonmagnetic component. The spin-dependent scattering of current carriers by the ferromagnetic components results in a modulation of the total resistance of the GMR by the angles between the magnetizations of the ferromagnetic components. An example of a GMR material, is the trilayer Permalloy/copper/Permalloy, where GMR operates to produce a minimum resistance for parallel alignment of the Permalloy magnetizations, and a maximum resistance for antiparallel alignment of the Permalloy magnetizations. The GMR ratio or coefficient for a multilayer system is defined as the fractional resistance change between parallel and antiparallel alignment of the adjacent layers, i.e., ratio=AR/R, where AR is the total decrease of electrical resistance as the applied magnetic field is increased to saturation and R is the resistance as measured in the state of parallel magnetization. This ratio can be as high as 10% for trilayer systems and more than 20% for multilayer systems.

The standard output characteristic of a GMR Wheatstone bridge is a typical S-shaped curve which e.g. is low for a negative magnetic field and high for a positive magnetic field. When the magnetic field oscillates around zero field, the output of the Wheatstone bridge switches from high to low. By feeding this signal to a trigger, a square wave is obtained which has the same frequency as the incoming oscillating magnetic field. For devices which give a low frequency variation in the generated magnetic signal, a frequency doubling in the outcoming sensor signal might be required. A frequency doubling is obtained if the output characteristic is changed from an S-shaped curve into a V-shaped curve where the output signal rises for increasing positive and negative fields.

It is also known from WO 99/08263 to provide a Wheatstone bridge arrangement of GMR devices with such a V-shaped output curve, for use as a signal multiplier. This utilizes the GMR bridge and the Barkhausen effect for increased sensitivity. An input signal drives an electromagnetic device such as an inductor to cause an oscillating magnetic field. The corresponding flux is collected by GMR bridge which produces an output with a first peak during the negative half of the input cycle, and a second peak during the positive half of the input cycle. A multiplier with a nonlinear voltage transfer curve is responsible for the generation of an output frequency which is twice the fundamental input frequency. The frequency doubling is obtained by means of electronics.

An object of the invention is to provide improved magnetic sensors using four magnetoresistive elements coupled in a bridge arrangement, where the output frequency is twice the fundamental input frequency, as well as methods of using and manufacturing the same.

According to a first aspect, the invention provides a bridge type magnetic sensor having four resistive elements in a bridge arrangement, two of the resistive elements on opposing sides of the bridge having a magnetoresistive characteristic such that their resistance increases with increasing positive magnetic field and with increasing negative magnetic field. An advantage of a sensor using such elements is that lower frequency changes can be recorded more accurately or precisely. It is very advantageous that for magnetic sensors which give a low frequency variation in the generated magnetic signal, a frequency doubling in the outcoming sensor signal is obtained. The frequency doubling is obtained because the output characteristic is changed from a conventional S-shaped curve into a V-shaped curve where the output signal rises for increasing positive and negative fields.

The resistive elements may be elongate elements, e.g. in strip form. Such elongate elements have a longitudinal direction parallel to the longest dimension.

An additional feature suitable for a dependent claim is all of the resistive elements being arranged to have a similar resistance characteristic with changes of temperature, and two of the resistive elements being arranged to be less sensitive to the magnetic field. This can help enable the desired bridge output characteristic.

Another such additional feature is the less sensitive elements being made less sensitive by differences in any of bias direction, direction of easy axis, linewidth, and orientation.

An additional feature suitable for a dependent claim is the other two of the four resistive elements being arranged to a magnetoresistance characteristic which is vertically mirrored with that of the first two of the resistive elements. This can help enable the desired bridge output characteristic with more sensitivity, but may involve more manufacturing costs.

Another such additional feature is all four of the elements having a bias direction perpendicular to the magnetic field being sensed, two of the elements on opposing sides of the bridge having an orientation perpendicular to the magnetic field being sensed, and the other two elements being oriented parallel to the field.

According to a second aspect, the invention provides a bridge type magnetic sensor having four resistive elements in a bridge arrangement, at least one of the elements having a resistance which increases with increasing positive magnetic field, and another of the elements having a resistance which increases with increasing negative magnetic field, arranged to combine so that a resistance of an output of the bridge increases with increasing positive magnetic field and with increasing negative magnetic field. An advantage of this arrangement is that the standard elements can be used with less modification.

An additional feature suitable for a dependent claim is all of the resistive elements being arranged to have a similar resistance characteristic with changes of temperature, and two of the resistive elements being arranged to be less sensitive to the magnetic field.

Another such additional feature is the less sensitive elements being made less sensitive by differences in any of bias direction, direction of easy axis, linewidth, and orientation.

Another such additional feature is all four elements being oriented perpendicular to the magnetic field being sensed, two of the elements on opposing sides of the bridge having a bias direction perpendicular to the magnetic field, and the other two elements having mutually opposing bias direction, both parallel to the field.

Another such additional feature is the magneto-resistive elements comprising GMR elements.

Any of the additional features can be combined together and combined with any of the aspects. Other advantages will be apparent to those skilled in the art, especially over other prior art. Numerous variations and modifications can be made without departing from the claims of the present invention. Therefore, it should be clearly understood that the form of the present invention is illustrative only and is not intended to limit the scope of the present invention.

How the present invention may be put into effect will now be described by way of example with reference to the appended drawings, in which:

FIG. 1 shows a characteristic of a known GMR sensor,

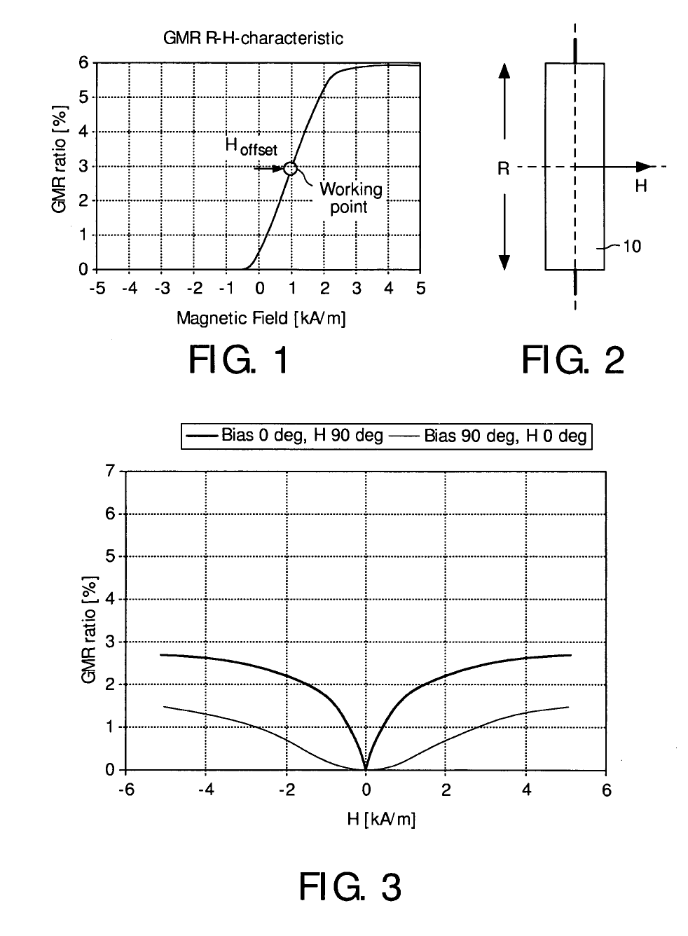

FIG. 2 shows an orientation of the GMR sensor,

FIG. 3 shows GMR ratio vs field for a GMR strip with two different bias directions and measurement directions,

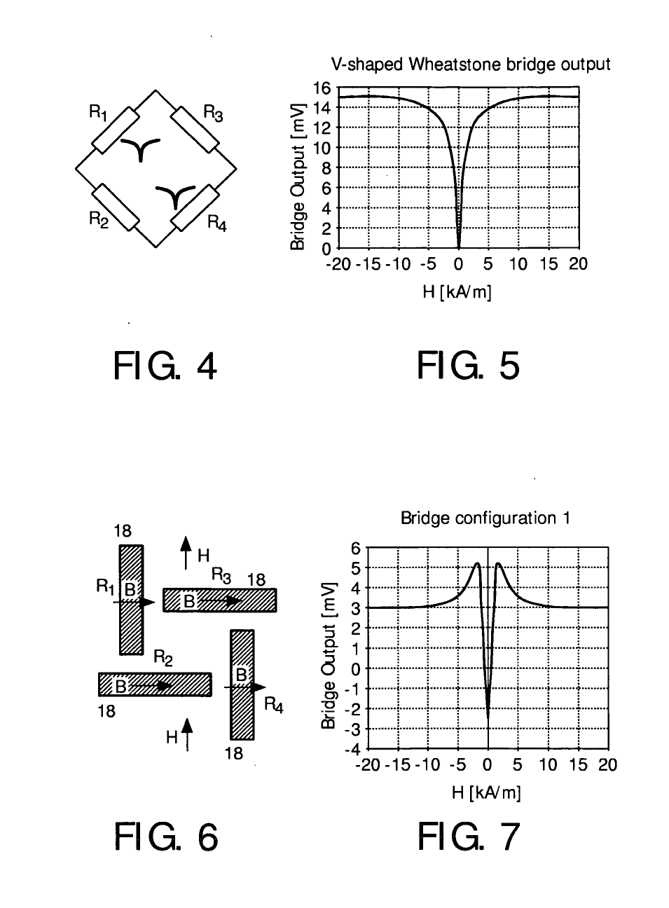

FIG. 4 shows a bridge according to a first embodiment,

FIG. 5 shows a graph of bridge output versus applied field for the example of FIG. 4,

FIG. 6 shows an orientation of bias directions and elements compared to the applied field for another embodiment,

FIG. 7 shows a graph of bridge output versus field, for the embodiment of FIG. 6,

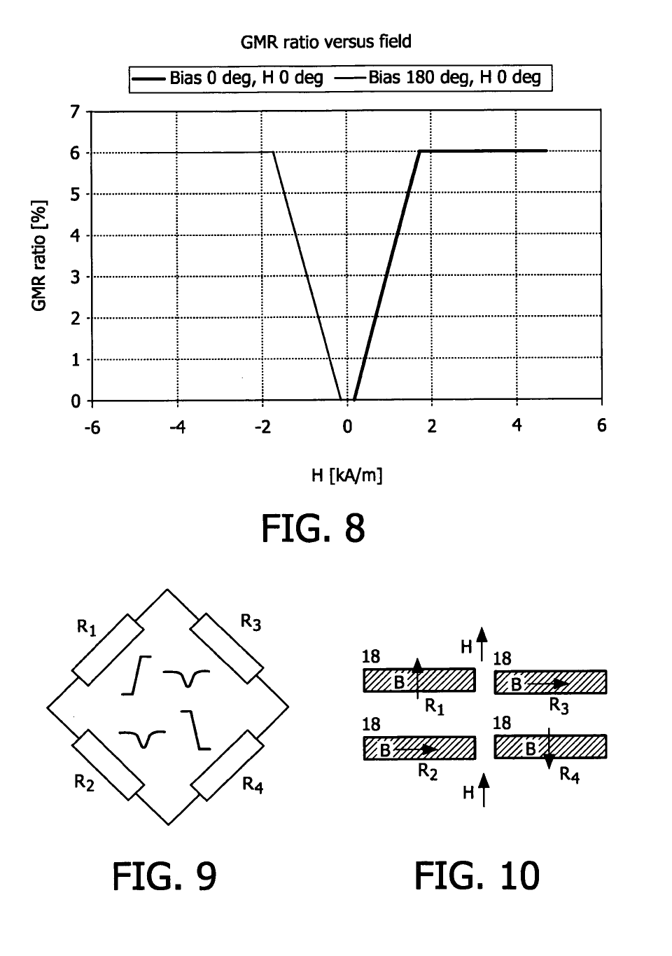

FIG. 8 shows a graph of GMR ratio versus field for two GMR devices having opposing characteristics,

FIG. 9 shows a bridge configuration according to another embodiment using the devices relating to FIG. 8,

FIG. 10 shows orientations and bias directions of four elements for the embodiment of FIG. 9, and

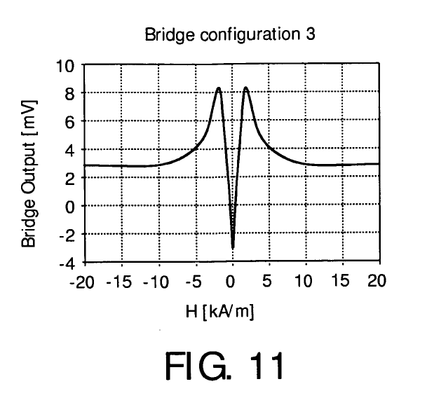

FIG. 11 shows a graph of bridge output versus applied field for the bridge of FIGS. 9 and 10.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

In any of the embodiments of the present invention the resistive and/or magnetoresistive elements are preferably elongate resistive elements, e.g. in strip form. These strips are shown schematically in the Figures. Such elongate elements have a longitudinal direction parallel to the longest dimension.

Before describing a first embodiment, to help understand the principles of operation, MR sensors will be introduced briefly. An MR sensor has a resistance that is dependent on an external magnetic field through the plane of the sensor. Different types of MR sensors exist. Sensors based on anisotropic magnetoresistance (AMR), have been used in magnetic recording heads for example. AMR sensors comprise a layer of anisotropical magnetic material. The magnetisation of this material is influenced by an external magnetic field. The angle between this magnetisation and the current determines the resistance value. The GMR (Giant MagnetoResistive) sensor consists of a stack of layers of which one has a fixed direction of magentisation and one layer of magnetic material of which the magnetic direction can be influenced by an external magnetic field. The measured resistance depends on the angle between the magnetisation directions.

Depending on the configuration an MR sensor is more sensitive in one direction and less sensitive in another direction in the plane of the sensor. A GMR sensor is more sensitive than an AMR sensor. By sending a current through the sensor, resistance changes can be translated to voltage changes which can be easily measured The resistance of the sensor can be measured within an integrated circuit with a dedicated detection circuit or from outside the integrated circuit with any suitable measurement arrangement.

GMR technology consists of a multi-layer stack of thin layers of magnetic and non-magnetic materials which are combined in such a way that the resistance of the complete stack changes when an external magnetic field is applied to the sensor. More specifically, the resistance is determined by the angle between two magnetic layers, the free layer and the reference layer being the highest when the magnetisations are anti-parallel and being the lowest when the magnetisations are parallel. The free magnetic layer can freely rotate such that the magnetisation in this layer roughly takes the direction of an externally applied field while the reference layer is a layer which has a fixed magnetisation direction. A further description of the stack can be found in U.S. Pat. No. 6,501,271 B1 ‘Robust Giant Magneto Resistive effect type multi layer sensor’.

Another type uses the large tunnel magnetoresistance (TMR) effect. TMR effects with amplitudes up to >50% have been shown, but because of the strong bias-voltage dependence, the useable resistance change in practical applications is typically less than 25%. TMR-based sensors have magnetic tunnel junctions (MTJs). MTJs basically contain a free magnetic layer, an insulating layer (tunnel barrier), a pinned magnetic layer, and an antiferromagnetic AF layer which is used to “pin” the magnetization of the pinned layer to a fixed direction. There may also be an underlayer and other layers which are not relevant to the principle of operation.

In general, both GMR and TMR result in a low resistance if the magnetisation directions in the multilayer are parallel, and in a high resistance when the orientations of the magnetisation are orthogonal. In TMR multilayers the sense current has to be applied perpendicular to the layer planes because the electrons have to tunnel through the insulating barrier layer. In GMR devices the sense current usually flows in the plane of the layers. In principle a sensor should have a large susceptibility to magnetic field (for high sensitivity) and should have little or no hysteresis.

For a GMR stack the maximum resistance change is typically between 6% and 15%. A magnetic sensor according to this principle typically consists of GMR material which is patterned into one or more almost rectangular stripes, often connected in the shape of a meander to achieve a certain resistance. The anisotropy axis of the free magnetisation layer in the stack is normally chosen along the axis of the stripe. In order to get the maximum resistance change in a field, the direction of the reference layer is chosen perpendicular to the axis of the strip. In this configuration the magnetic field is also applied perpendicular to the length axis of the strip in order to give the maximum resistance change.

In FIG. 1 the R-H output characteristic of such a GMR sensor element 10 of FIG. 2 is shown in which the y axis shows the normalized change in resistance R and the x axis shows the applied magnetic field H. The direction of applied magnetic field with respect to the longitudinal direction of the resistor strip is indicated in the diagram on the right hand side of FIG. 1. From FIG. 1 it becomes clear that the most sensitive and linear part of the GMR characteristic is not around the zero field point but around some finite offset-field H_{offset}. This observed shift in the R-H-characteristic is caused by internal magnetic fields and couplings in the GMR stack itself and can be tuned or varied within a certain range to yield a characteristic suitable for a specific application.

The sensitivity of the characteristic is dependent on the geometry of the sensor and therefore also can be adapted to a specific application. In this document, the point of maximum sensitivity and linearity is called the working point of the sensor which is also indicated in FIG. 1. The GMR sensor can be set in its working point by applying a constant magnetic field with a field strength equal to H_{offset} to it. Such an external magnetic field could e.g. be generated by a coil integrated together with the GMR stripes or by a set of permanent magnets which are placed around the sensor. These permanent magnets could be single pieces of (hard) magnetic material but it is also possible to use thin film deposition (e.g. sputter deposition of CoPt) and lithography techniques (lift-off) to make integrated permanent magnets onto the chip die itself. This has the advantage of being cheaper than single external magnets, and the alignment of the magnets with respect to the sensor can be much more accurate. This technique of integrated permanent magnets is e.g. known in hard disk and magnetic tape readheads where an integrated magnetic field can be used for the biasing or stabilisation of the magneto-resistive sensor element.

It is clear from FIG. 1 that a variation in the field strength of this permanent magnetic field will causes a variation in the resistance of the GMR element. Lower field strengths will reduce the resistance while higher field strengths will increase resistance. Therefore, a modulation of the permanent magnetic field will cause a modulation in the output of the sensor. The embodiments of the present invention are based on sensing such modulations caused by movement of magnetically permeable elements within the field.

An aim is to provide a V-shaped response using a standard GMR stack. It is known that if the resistance of a GMR strip is measured as a function of the magnetic field strength, the resistance change shows a V -shaped curve when the measuring field is placed at 90 degrees with respect to the direction of the exchange biasing field. An example of such a resistance curve is given in FIG. 3 (upper line). Such a curve would already have the required characteristic where the resistance and thus the output signal rises with increasing positive and negative magnetic fields. Although such a stand-alone GMR element could be used to generate the desired signals, it is often desired to implement such an element into a Wheatstone bridge configuration. Advantages of a Wheatstone bridge configuration are the temperature compensation and the output signal which modulates around zero Volts which allows easier signal conditioning. Such a Wheatstone bridge configuration is given in FIG. 4. R₁ and R₄ are the magnetoresistive elements showing the V-shaped characteristic. In order to get the V-shaped curve at the output of the Wheatstone bridge, it is required that the resistors R₂ and R₃ have a resistance value which is independent of the magnetic field strength or have a characteristic which is vertically mirrored with respect to R₁ and R₄. For a good temperature compensation and minimal drift in output voltage it is required that the resistors R₂ and R₃ can optionally be made of the same material as magnetoresistors R₁ and R₄.

In order to make these resistors insensitive to the external magnetic field, magnetic flux shields can be placed above or below these resistors. In this case an output curve as drawn in FIG. 5 would be the result. To make such a Wheatstone bridge would require an additional step in which these flux shields or guides are deposited and patterned. If the presence of these flux shields also affects the magnetic field lines entering the sensitive resistors R₁ and R₄, then another way to achieve the desired result is to change some of the element parameters. Examples include the bias direction, the direction of the easy axis, the linewidth and/or the orientation of the GMR element with respect to the external magnetic field in such a way that the element is less sensitive to the applied magnetic field.

As another example, if the bias direction is taken parallel to the longitudinal direction of the GMR element and the complete element is positioned in such a way that the external field is perpendicular to the longitudinal direction of the element, the resistance varies much less with magnetic field. The resistance change of such an element is given in FIG. 3 (lower line). It is clearly shown that the upper curve (representing R₁ and R₄) changes much more rapidly than the lower line. By reducing the linewidth of the elements R₂ and R₃ the change of the lower curve around zero field can be reduced even more. FIG. 6 shows the direction of the bias and of the GMR elements with respect to the applied field while FIG. 7 shows the output curve of such a Wheatstone bridge. The advantage of this construction is that a V-shaped output characteristic can be obtained by the standard GMR stack design with only one bias direction by using only a change in the Wheatstone bridge design.

Another way to achieve a similar result uses the addition of normal R-H curves. A normal resistance versus magnetic field curve (R-H) of a GMR strip is obtained when the field is applied in a direction parallel to the exchange bias direction. Such a normal curve is given in FIG. 8 (right half). When the exchange bias direction is reversed with respect to the applied field direction, the R-H-curve will also be reversed (FIG. 8, left half). By adding these curves, again a V-shaped curve can be obtained. This addition can be carried out in a Wheatstone bridge if it is configured according to FIG. 9. Resistor R₁ represents an element with a normal R-H-curve using one direction of the bias while resistor R₄ represents an element with a reversed R-H curve using a reversed bias direction. Resistors R₂ and R₃ are the same as in FIGS. 6 and 7. FIG. 10 shows the orientation of the elements and their bias directions while FIG. 11 shows the output characteristic of such a Wheatstone bridge. An advantage of this design is that the standard GMR stack and the standard design of the Wheatstone bridge can be used while only changing the directions of the bias. This can be done using local heating.

Other combinations of bias direction, element direction, easy axis direction and line width can yield other Wheatstone bridge output characteristics which might be of advantage for particular applications. Other variations within the claims can be conceived.

1. A bridge type magnetic sensor having four resistive elements in a bridge arrangement, two of the resistive elements on opposing sides of the bridge having a magnetoresistive characteristic such that their resistance increases with increasing positive magnetic field and with increasing negative magnetic field.

2. The sensor according to claim 1 wherein the four resistive elements are arranged to have a similar resistance characteristic with changes of temperature, and two of the resistive elements being arranged to be less sensitive to the magnetic field.

3. The sensor according to claim 2, wherein the less sensitive elements are made less sensitive by differences in any of bias direction, direction of easy axis, linewidth, and orientation.

4. The sensor according to claim 2, wherein the other two of the four resistive elements are arranged to a magnetoresistance characteristic which is vertically mirrored with that of the first two of the resistive elements.

5. The sensor according to claim 1, wherein all four of the elements having a bias direction perpendicular to the magnetic field being sensed, two of the elements on opposing sides of the bridge having an orientation perpendicular to the magnetic field being sensed, and the other two elements being oriented parallel to the field.

6. A bridge type magnetic sensor having four resistive elements in a bridge arrangement, at least one of the elements having a resistance which increases with increasing positive magnetic field, and another of the elements having a resistance which increases with increasing negative magnetic field, arranged to combine so that a resistance of an output of the bridge increases with increasing positive magnetic field and with increasing negative magnetic field.

7. The sensor according to claim 6, wherein all four of the resistive elements are arranged to have a similar resistance characteristic with changes of temperature, and two of the resistive elements being arranged to be less sensitive to the magnetic field.

8. The sensor according to claim 7, wherein the less sensitive elements are made less sensitive by differences in any of bias direction, direction of easy axis, linewidth, and orientation.

9. The sensor according to claim 6, wherein all four elements are oriented perpendicular to the magnetic field being sensed, two of the elements on opposing sides of the bridge having a bias direction perpendicular to the magnetic field, and the other two elements having mutually opposing bias direction, both parallel to the field.

10. The sensor according to claim 1, wherein the magnetoresistive elements comprise GMR elements. mag
